(19) United States
(12) Patent Application Publication
(10) Pub. No.: US 2024/0088827 A1
(43) Pub. Date: Mar. 14, 2024

(54) SOLAR CELL ARRAY MOUNTING SYSTEM AND METHOD

(71) Applicant: Andrew Thomas, Northridge, CA (US)

(72) Inventor: Andrew Thomas, Northridge, CA (US)

(21) Appl. No.: 18/464,827

(22) Filed: Sep. 11, 2023

Related U.S. Application Data
(60) Provisional application No. 63/375,384, filed on Sep. 12, 2022.

(51) Int. Cl. H02S 40/22; H02S 20/32

(52) U.S. Cl. CPC H02S 40/22; H02S 20/32

(57) ABSTRACT

A solar cell array assembly comprises a housing having an aperture and an interior surface that defines a cavity. The solar array assembly further comprises a solar cell array including a plurality of solar cells attached to the interior surface of the housing, and a reflector located within the cavity and configured to reflect light rays that enter the cavity through the aperture toward the plurality of solar cells.

This application claims the benefit of U.S. provisional patent application No. 63/375,384, filed on Sep. 12, 2022, which is incorporated by reference herein in its entirety.

### TECHNOLOGY FIELD

The present invention generally pertains to solar cell arrays, and more particularly, to a technique for mounting a solar cell array in a housing.

### BACKGROUND

Solar cell deployment has been increasing steadily over the past 20 years and is predicted to continue to grow as the demand for renewable energy becomes ever more imperative. Across the globe, surface area on land is relatively abundant, and a common practice amongst solar companies and contractors is to construct massive solar farms that generate tens of thousands of kilowatt-hours per day. A downside of this method of harnessing solar energy is that about 66% of the energy is lost in the generation, transmission, and distribution steps of the process by the time it reaches consumers. Another downside is that solar farms consume a significant amount of area and are often located in remote locations, miles away from the energy's intended destination, where they may be harmful to certain populations of wildlife.

### BRIEF DESCRIPTION OF THE DRAWINGS

One or more embodiments of the present invention are illustrated by way of example and not limitation in the figures of the accompanying drawings, in which like references indicate similar elements.

FIG. 1A illustrates a top view of a cylindrical solar cell array housing.

FIG. 1B illustrates side view of the cylindrical solar cell array housing shown in FIG. 1A.

FIG. 2 illustrates an example of a cylindrical solar cell array assembly.

FIG. 3 illustrates an example of a hyperboloid solar cell array assembly.

FIG. 4 illustrates an example of a rectangular prism shaped solar cell array assembly.

FIG. 5 schematically illustrates an example of the orientation of the solar cells relative to the origination direction of light rays entering the housing through the aperture.

### DETAILED DESCRIPTION

Introduced here is a solar cell mounting technique which addresses at least some of the above-mentioned issues, by increasing the number of solar cells per unit area of land or structure (e.g., rooftop) on which the solar cell array is to be mounted. That is, the mounting technique enables a given number of conventional solar cells to be located within a much smaller area of land or structure than prior mounting techniques, and enables a greater number of solar cells to be provided within a given area.

More specifically, introduced herein are embodiments of a solar cell array assembly that comprises a housing that has an aperture and an interior surface that defines a substantially-enclosed cavity (e.g., enclosed except for the aperture). Stated another way, the housing and the aperture are sized and shaped such that, if the aperture were replaced by a surface that is part of and contiguous with the outer surface of the housing, that surface corresponding to the aperture would constitute only a small fraction of the total surface area of the outer surface of the housing (e.g., less than 20%, and potentially much less). The solar array assembly further comprises a solar cell array including a plurality of solar cells attached to the interior surface of the housing, and a reflector located within the cavity and configured to reflect light rays that enter the cavity through the aperture toward the plurality of solar cells. In at least some embodiments, an inner surface of the housing (and therefore the solar cells that are mounted to it) is oriented at a significant angle relative to the surface to which the housing is mounted (e.g., land or rooftop); this angle can be 90 degrees or close to 90 degrees. In other words, the solar cells are spread out within the housing generally along an axis that is parallel to, or nearly parallel to, the expected direction (or expected average direction over time) of light rays from the intended energy source (e.g., the sun); and they are oriented so that their light receiving surfaces are parallel to, or nearly parallel to, the direction (or time-average direction) of incident light rays from the intended energy source. This is made possible, in at least some embodiments, by providing a reflector located within the cavity at the bottom of the housing, that redirects the incident light rays onto the solar cells mounted on the inner wall(s) of the housing. This technique, therefore, allows many solar cells to be spread out in a direction that is perpendicular to or close to perpendicular to the surface of land or rooftop on which the mounting system is mounted, thereby enabling more solar cells to be provided per unit area of land or rooftop.

This technique is in contrast with conventional solar cell arrays, in which the light receiving surfaces of the solar cells are all oriented as close as possible to perpendicular to the expected direction of incident light rays, and are oriented much closer to parallel to the surface of land or rooftop on which the solar cells are mounted.

In various embodiments, the housing may have the shape of a hollow cylinder. In other embodiments, the housing can have the shape of a hyperboloid, a hollow rectangular prism, or other shape. A control system and one or more motors provide axial rotation to enable the azimuth and elevation of the housing to be continuously adjusted, so that the aperture tracks the sun across the sky during the course of the day.

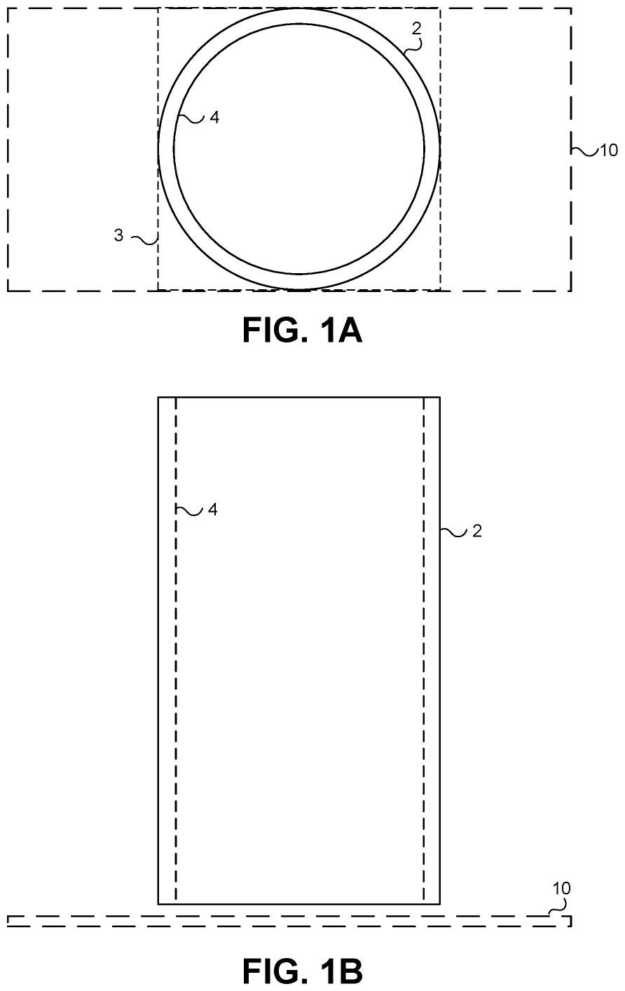

Refer now to FIGS. 1A and 1B, which each show a comparison of the footprint of a solar cell array housing 2 according to the technique introduced here, for a cylindrical embodiment, compared to that of a conventional solar cell array 10. More specifically, FIG. 1A shows a top view of a cylindrical solar cell array housing 2, while FIG. 1B shows the corresponding side view. A hollow cylindrical housing 2 has a circular cross-section, as shown in FIG. 1A. If a square 3 is drawn evenly around that circular cross-section of the housing 2, so that the circular cross-sectional area inscribes the square 3, the surface area of the square 3 is much smaller than the surface area of the inner wall 4 of the cylindrical housing 2 (assuming the thickness of the wall of the cylindrical housing 2 is negligible compared to its diameter).

Additionally, the overall footprint of the housing 2 is much smaller than that of a conventional solar cell array 10. The technique introduced here uses this concept to arrange many more solar cells in a given footprint area that is smaller than with traditional solar panel arrays. A typical commercial solar panel 10 is rectangular (as shown) and measures about 6.5 feet×3.25 feet, which equates to a surface area of about 21 square feet. In contrast, for a cylinder that is 6.5 feet tall and 3.25 feet in diameter, the surface area on the inside of cylinder (again assuming the wall thickness is negligible compared to the diameter) is about 66 square feet, i.e., it is considerably larger than the surface area of the conventional solar panel. These characteristics are useful in generating solar energy in a metropolis, heavily wooded areas, or even remote locations far from established power grids.

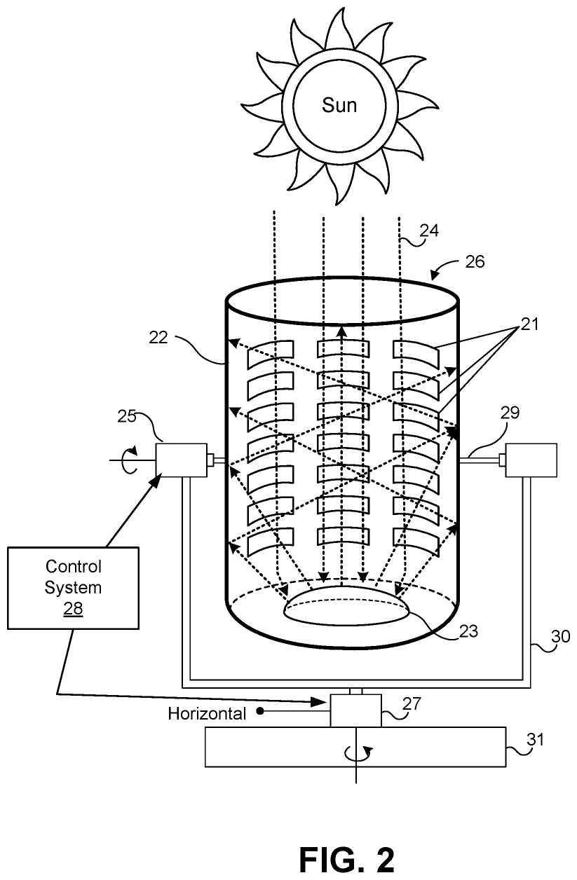

FIG. 2 shows in more detail an example of an embodiment with a cylindrical solar cell array assembly. As shown, one or more arrays of solar cells 21 are disposed along most or all of the interior surface of a hollow cylindrical housing 22 (for the sake of providing a clearer and simpler illustration, the housing 22 is illustrated as being transparent, not all solar cells are shown, and features in the figure are not necessarily drawn to scale). A convex mirror 23 (or other suitable type of reflector) is mounted to the bottom end of the inside of the cylindrical housing 22, and is positioned and shaped so as to reflect incident light rays 24 from the sun (or other intended energy source) that enter the housing 22 through the aperture 26, toward the solar cells 21 on the inner wall of the housing 22. Note that in some embodiments, the mirror 23 (or other reflector) may be mounted within the cavity somewhere other than at the bottom of the housing.

The housing 22 can be movably coupled to an elevation motor 25, which provides rotation of the housing 22 about a horizontal axis in order to change the elevation angle of the aperture 26. The housing 22 can also be coupled to an azimuth motor 27, which provides rotation of the housing 22 about a vertical axis in order to change the azimuth angle of the aperture 26. The motors 25 and 27 can be controlled by a simple control system 28, which may include conventional electronics and software. In this manner, the motors 25 and 27 can be controlled so as to aim the housing 22 so that the aperture 26 tracks the sun across the sky during the course of the day. The housing 22 can be coupled to one or more axles 29 that movably engage the elevation motor 25. The housing 22, elevation motor 25 and axle(s) 29 can collectively be coupled to a support structure 30 that is movably engaged with the azimuth motor 27. The azimuth motor 27 can be mounted to a base 31, which is designed to be attached to a surface such as land or the roof of the building. Note that many other different types of structures can be used to support the housing and motors instead of the illustrated configuration.

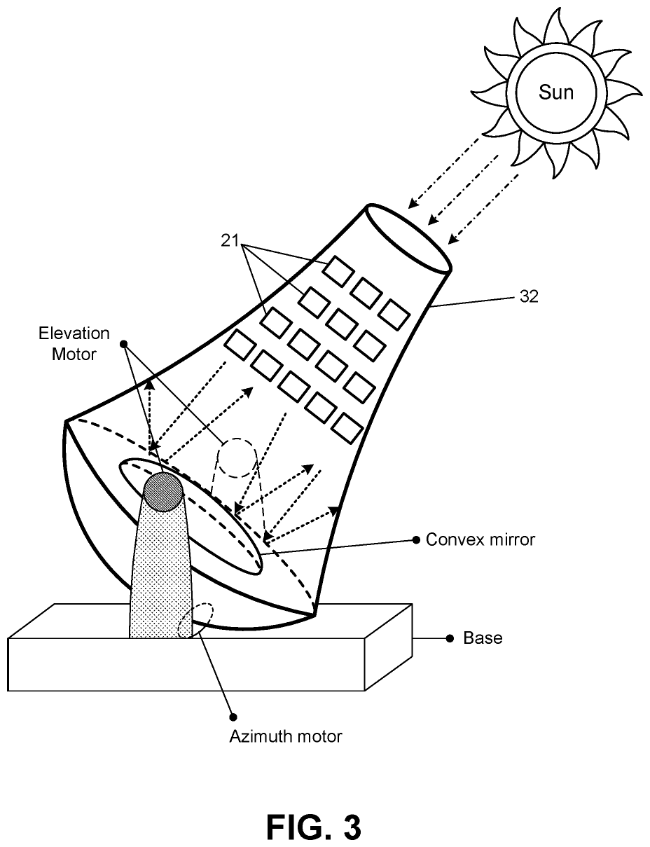

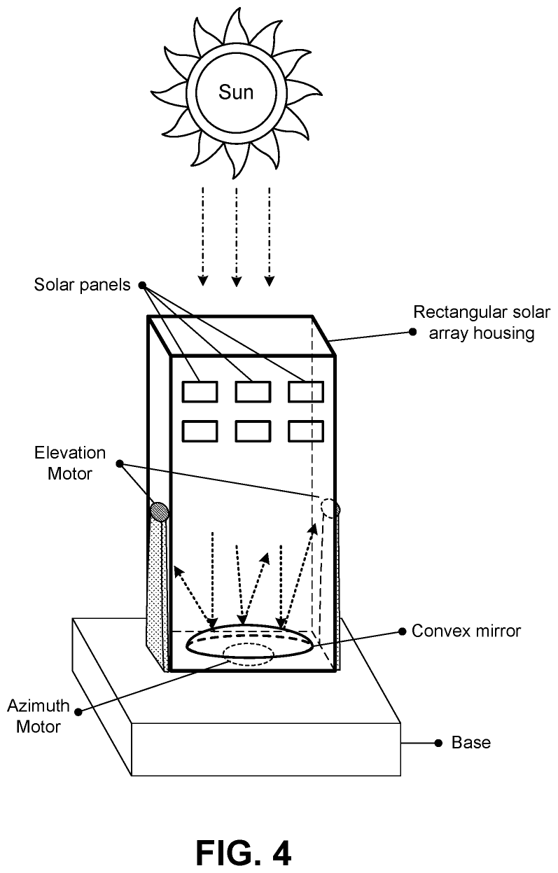

As mentioned above, the solar cell array housing can alternatively have a shape other than that of a cylinder. For example, as shown in FIG. 3, the housing 32 (or at least its inner surface) can have a hyperboloid shape. Or, as shown in FIG. 4, the housing 42 (or at least its inner surface) can have a rectangular prism shape. In other embodiments, other shapes may be used for the housing within the scope of the technique introduced here, such as a tetrahedron or partial tetrahedron, a sphere or partial sphere, etc., or an approximation of any of the above-mentioned shapes (e.g., such as may be assembled from many individual connected flat surfaces).

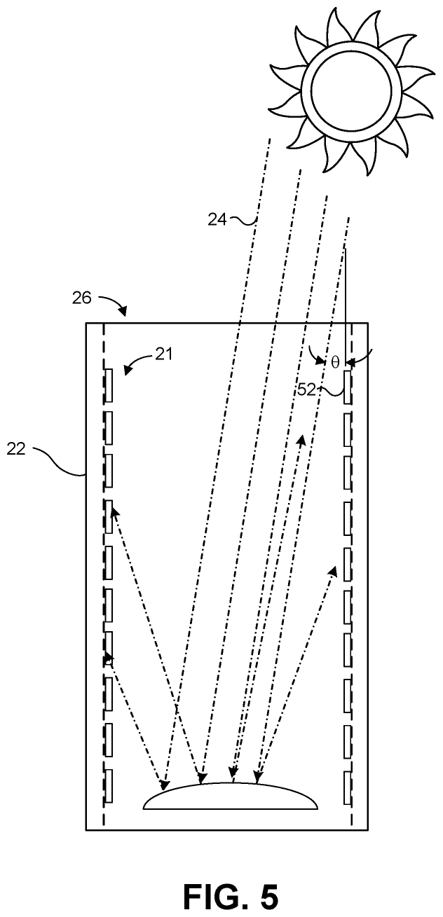

In at least some embodiments, as shown schematically in FIG. 5 for a cylindrical embodiment, the solar cells 21 are mounted within the housing 22 so that at any given time, the light-receiving surfaces 52 of at least some of the solar cells 21 are oriented at an offset angle θ of less than 60 degrees from the origination direction of the light rays 24 that enter the cavity of the housing 22 through the aperture 26. Note that features in FIG. 5 are not necessarily drawn to scale. Further, in at least some embodiments, at any given time, the light-receiving surfaces 52 of at least some of the solar cells 21 are oriented at an offset angle θ of less than 45 degrees from the origination direction of the light rays 24 that enter the cavity through the aperture 26. In at least some embodiments, when the light source (e.g., the sun) is centered in the aperture 26 (i.e., when the housing is properly aimed at the light source), as shown in FIGS. 2 through 4, the light-receiving surfaces of at least some of the solar cells 21 mounted in the housing 22 are oriented at an offset angle θ of zero degrees from (i.e., they are parallel to) the origination direction of the light rays 24 that enter the cavity through the aperture 26.

To facilitate illustration, FIGS. 2 through 5 each show unused surface area between individual solar cells 21 on the inner surface of the housing 22. However, in at least some embodiments, at least some of the solar cells 21 may be mounted adjacent to each other on the inner surface of the housing 22, so that there is no significant unused surface area between them. To the extent there is any unused surface area between some or all solar cells 21 on the inner surface of the housing 22, it may be desirable to add a highly reflective coating on such unused surface area, so that any light impinging on the unused surface area is reflected and is likely to impinge upon one or more other solar cells on the inner surface of the housing 22, thereby increasing efficiency of the system.

### EXAMPLES

The technique introduced above, in at least some embodiments, can be characterized by the following numbered examples:
1. A solar cell array assembly comprising:
   a housing having an aperture and an interior surface that defines a cavity;
   a solar cell array including a plurality of solar cells attached to the interior surface of the housing; and a reflector located within the cavity and configured to reflect light rays that enter the cavity through the aperture toward the plurality of solar cells.
2. The solar cell array assembly of example 1, wherein at least some of the solar cells have light-receiving surfaces that are oriented at an offset angle of less than 60 degrees from an origination direction of the light rays that enter the cavity through the aperture.
3. The solar cell array assembly of example 1, wherein at least some of the solar cells have light-receiving surfaces that are oriented at an offset angle of less than 45 degrees from an origination direction of the light rays that enter the cavity through the aperture.
4. The solar cell array assembly of example 1, wherein at least some of the solar cells have light-receiving surfaces that are oriented parallel to an origination direction of the light rays that enter the cavity through the aperture when a source of the light rays is centered in the aperture.
5. The solar cell array assembly of example 1, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least twice the maximum cross-sectional area of the housing.
6. The solar cell array assembly of example 1, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum cross-sectional area of the housing.
7. The solar cell array assembly of example 1, wherein the reflector is a convex mirror.
8. The solar cell array assembly of example 1, wherein the interior surface of the housing is cylindrical.
9. The solar cell array assembly of example 1, wherein the interior surface of the housing is hyperboloid.
10. The solar cell array assembly of example 1, wherein the interior surface of the housing is rectangular cuboid.
11. The solar cell array assembly of example 1, further comprising a control mechanism to enable the aperture of the housing to track a path of the sun.
12. The solar cell array assembly of example 1, further comprising:
   a base movably coupled to the housing;
   a first motor to control an azimuth angle of the aperture; and
   a second motor to control an elevation angle of the aperture.
13. The solar cell array assembly of example 12, further comprising control circuitry to control the first motor and the second motor to cause the aperture to track a path of the sun.
14. A solar cell array assembly comprising:
   a housing having an aperture and a cylindrical interior surface that collectively define a partially-enclosed cavity;
   a solar cell array including a plurality of solar cells attached to the interior surface of the housing, the solar cell array covering substantially all of the cylindrical interior surface; and
   a convex reflector located within the cavity at a bottom interior surface the housing and configured to reflect light rays that enter the cavity through the aperture toward the plurality of solar cells;
   a first motor coupled to the housing to provide rotation of the housing along a first axis;
   a second motor coupled to the housing to provide rotation of the housing along a second axis that is non-parallel to the first axis;
   control circuitry configured to control the first motor and the second motor to cause the aperture of the housing to track a path of the sun; and
   base coupled to the housing.
15. The solar cell array assembly of example 14, wherein at least some of the solar cells have light-receiving surfaces that are oriented at an offset angle of less than 60 degrees from an origination direction of the light rays that enter the cavity through the aperture.
16. The solar cell array assembly of example 14, wherein at least some of the solar cells have light-receiving surfaces that are oriented at an offset angle of less than 45 degrees from an origination direction of the light rays that enter the cavity through the aperture.
17. The solar cell array assembly of example 14, wherein at least some of the solar cells have light-receiving surfaces that are oriented parallel to an origination direction of the light rays that enter the cavity through the aperture.
18. The solar cell array assembly of example 14, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least two times the maximum the cross-sectional area of the housing.
19. The solar cell array assembly of example 14, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum the cross-sectional area of the housing.
20. A solar cell array assembly comprising:
   a solar cell array including a plurality of solar cells; and
   a housing having an aperture through which to receive light rays from an energy source, and having a surface on which the solar cell array is mounted, such that when the solar cell array assembly is in use, a light receiving surface of at least a portion of the solar cell array is oriented at an offset angle of less than 45 degrees from an origination direction of the light rays from the energy source that pass through the aperture.
21. The solar cell array assembly of example 20, wherein at least a portion of the solar cell array is oriented parallel to an origination direction of the light rays from the energy source.
22. The solar cell array assembly of example 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least twice the maximum the cross-sectional area of the housing.
23. The solar cell array assembly of example 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum the cross-sectional area of the housing.
24. The solar cell array assembly of example 20, further comprising a convex reflector.
25. The solar cell array assembly of example 20, further comprising:
   a base movably coupled to the housing;
   an azimuth motor to control an azimuth angle of the housing;
   an elevation motor to control an elevation angle of the housing; and
   a control mechanism to enable the housing to track a path of the sun.
26. The solar cell array assembly of example 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least five times the maximum the cross-sectional area of the housing.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A solar cell array assembly comprising:
a housing having an aperture and an interior surface that defines a cavity;
a solar cell array including a plurality of solar cells attached to the interior surface of the housing; and
a reflector located within the cavity and configured to reflect light rays that enter the cavity through the aperture toward the plurality of solar cells.

2. The solar cell array assembly of claim 1, wherein at least some of the solar cells have light-receiving surfaces that are oriented at an offset angle of less than 60 degrees from an origination direction of the light rays that enter the cavity through the aperture.

3. The solar cell array assembly of claim 1, wherein at least some of the solar cells have light-receiving surfaces that are oriented at an offset angle of less than 45 degrees from an origination direction of the light rays that enter the cavity through the aperture.

4. The solar cell array assembly of claim 1, wherein at least some of the solar cells have light-receiving surfaces that are oriented parallel to an origination direction of the light rays that enter the cavity through the aperture when a source of the light rays is centered in the aperture.

5. The solar cell array assembly of claim 1, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least twice the maximum cross-sectional area of the housing.

6. The solar cell array assembly of claim 1, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum cross-sectional area of the housing.

7. The solar cell array assembly of claim 1, wherein the reflector is a convex mirror.

8. The solar cell array assembly of claim 1, wherein the interior surface of the housing is cylindrical.

9. The solar cell array assembly of claim 1, wherein the interior surface of the housing is hyperboloid.

10. The solar cell array assembly of claim 1, wherein the interior surface of the housing is rectangular cuboid.

11. The solar cell array assembly of claim 1, further comprising a control mechanism to enable the aperture of the housing to track a path of the sun.

12. The solar cell array assembly of claim 1, further comprising:
a base movably coupled to the housing;
a first motor to control an azimuth angle of the aperture; and
a second motor to control an elevation angle of the aperture.

13. The solar cell array assembly of claim 12, further comprising control circuitry to control the first motor and the second motor to cause the aperture to track a path of the sun.

14. A solar cell array assembly comprising:
a housing having an aperture and a cylindrical interior surface that collectively define a partially-enclosed cavity;
a solar cell array including a plurality of solar cells attached to the interior surface of the housing, the solar cell array covering substantially all of the cylindrical interior surface; and
a convex reflector located within the cavity at a bottom interior surface the housing and configured to reflect light rays that enter the cavity through the aperture toward the plurality of solar cells;
a first motor coupled to the housing to provide rotation of the housing along a first axis;
a second motor coupled to the housing to provide rotation of the housing along a second axis that is non-parallel to the first axis;
control circuitry configured to control the first motor and the second motor to cause the aperture of the housing to track a path of the sun; and
base coupled to the housing.

15. The solar cell array assembly of claim 14, wherein at least some of the solar cells have light-receiving surfaces that are oriented at an offset angle of less than 60 degrees from an origination direction of the light rays that enter the cavity through the aperture.

16. The solar cell array assembly of claim 14, wherein at least some of the solar cells have light-receiving surfaces that are oriented at an offset angle of less than 45 degrees from an origination direction of the light rays that enter the cavity through the aperture.

17. The solar cell array assembly of claim 14, wherein at least some of the solar cells have light-receiving surfaces that are oriented parallel to an origination direction of the light rays that enter the cavity through the aperture.

18. The solar cell array assembly of claim 14, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least two times the maximum the cross-sectional area of the housing.

19. The solar cell array assembly of claim 14, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum the cross-sectional area of the housing.

20. A solar cell array assembly comprising:
a solar cell array including a plurality of solar cells; and
a housing having an aperture through which to receive light rays from an energy source, and having a surface on which the solar cell array is mounted, such that when the solar cell array assembly is in use, a light receiving surface of at least a portion of the solar cell array is oriented at an offset angle of less than 45 degrees from an origination direction of the light rays from the energy source that pass through the aperture.

21. The solar cell array assembly of claim 20, wherein at least a portion of the solar cell array is oriented parallel to an origination direction of the light rays from the energy source.

22. The solar cell array assembly of claim 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least twice the maximum the cross-sectional area of the housing.

23. The solar cell array assembly of claim 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least three times the maximum the cross-sectional area of the housing.

24. The solar cell array assembly of claim 20, further comprising a convex reflector.

25. The solar cell array assembly of claim 20, further comprising:
a base movably coupled to the housing;
an azimuth motor to control an azimuth angle of the housing;
an elevation motor to control an elevation angle of the housing; and
a control mechanism to enable the housing to track a path of the sun.

26. The solar cell array assembly of claim 20, wherein the housing has a maximum cross-sectional area representing an outer footprint of the housing in a plane perpendicular to an angle at which the light rays enter the cavity through the aperture, and wherein the solar cell array occupies an area on the interior surface of the housing that is at least five times the maximum the cross-sectional area of the housing.
